(19) United States
(12) Patent Application Publication
(10) Pub. No.: US 2026/0206429 A1
(43) Pub. Date: Jul. 16, 2026

(54) DISPLAY DEVICE

(71) Applicant: Sharp Display Technology Corporation, Kameyama City, Mie (JP)

(72) Inventor: Tadayoshi MIYAMOTO, Kameyama City, Mie (JP)

(21) Appl. No.: 19/135,144

(22) PCT Filed: Dec. 12, 2022
(86) PCT No.: PCT/JP2022/045628

§ 371 Date: Jun. 3, 2025

(51) Int. Cl. H10K 59/124; H10K 59/121

(52) U.S. Cl. CPC H10K 59/124; H10K 59/1213

(57) ABSTRACT

A base substrate, a TFT layer provided on the base substrate, and a light-emitting-element layer having a top-emission configuration and provided on the TFT layer are provided. The TFT layer includes: a first TFT having a first semiconductor layer formed of polysilicon; and a second TFT having a second semiconductor layer formed of oxide semiconductor. The first and second TFTs are provided for each of subpixels. A planarization film provided to the first and second TFTs toward the light-emitting-element layer is provided so that a transmittance of light having a wavelength of 450 nm or shorter is set lower than a transmittance of light having a wavelength longer than 450 nm.

### TECHNICAL FIELD

The present invention relates to a display device.

### BACKGROUND ART

In recent years, light-emitting organic electroluminescence (EL) display devices using organic EL elements have attracted attention as a replacement for liquid crystal display devices. An organic EL display device is provided with a plurality of thin-film transistors (hereinafter also referred to as “TFTs”) for each of subpixels. A subpixel is a minimum unit of an image. Here, examples of a well-known semiconductor layer that constitutes a TFT include: a semiconductor layer made of polysilicon having high mobility; and a semiconductor layer made of oxide semiconductor such as In—Ga—Zn—O and exhibiting low current leakage.

For example, Patent Document 1 discloses a display device having a hybrid structure in which a first TFT made of polysilicon semiconductor and a second TFT made of oxide semiconductor are formed on a substrate.

### CITATION LIST

### Patent Literature

[Patent Document 1] Japanese Unexamined Patent Application Publication No. 2020-017558

### SUMMARY OF INVENTION

### Technical Problem

The hybrid organic EL display device is provided with subpixels each including a TFT formed of polysilicon and a TFT formed of oxide semiconductor. In producing the hybrid organic EL display device, a technique is proposed to use, for example, polysilicon for a TFT required to have power to drive and oxide semiconductor for a TFT required to hold charges. Here, as to the TFT formed of oxide semiconductor, the characteristics are likely to deteriorate by moisture and light. Hence, even if the hybrid organic EL display device is a top-emission organic EL display device, such light as stray light of the emitted light might intrude into the TFT formed of oxide semiconductor and cause deterioration in the characteristics of the TFT.

The present invention is conceived in view of the above problem, and sets out to reduce light-induced deterioration of a thin-film transistor formed of oxide semiconductor and included in a hybrid display device.

### Solution to Problem

In order to achieve the above object, a display device according to the present invention includes: a base substrate; a thin-film transistor layer provided on the base substrate; and a light-emitting-element layer having a top-emission configuration and provided on the thin-film transistor layer. The thin-film transistor layer includes: a first thin-film transistor having a first semiconductor layer formed of polysilicon; a second thin-film transistor having a second semiconductor layer formed of oxide semiconductor; and a planarization film provided to the first thin-film transistor and the second thin-film transistor toward the light-emitting-element layer. The first thin-film transistor and the second thin-film transistor are provided for each of a plurality of subpixels included in a display region. The planarization film is provided so that a transmittance of light having a wavelength of 450 nm or shorter is set lower than a transmittance of light having a wavelength longer than 450 nm.

### Advantageous Effect of Invention

The present invention can reduce light-induced deterioration of a thin-film transistor formed of oxide semiconductor and included in a hybrid display device.

### BRIEF DESCRIPTION OF DRAWINGS

FIG. 1 is a plan view of a schematic configuration of an organic EL display device according to a first embodiment of the present invention.

FIG. 2 is a plan view of a display region of the organic EL display device according to the first embodiment of the present invention.

FIG. 3 is a cross-sectional view of the display region of the organic EL display device according to the first embodiment of the present invention.

FIG. 4 is an equivalent circuit diagram of a TFT layer included in the organic EL display device according to the first embodiment of the present invention.

FIG. 5 is a cross-sectional view of an organic EL layer included in the organic EL display device according to the first embodiment of the present invention.

### DESCRIPTION OF EMBODIMENTS

Embodiments of the present invention will be described in detail below with reference to the drawings. Note that the present invention shall not be limited to the embodiments below.

### First Embodiment

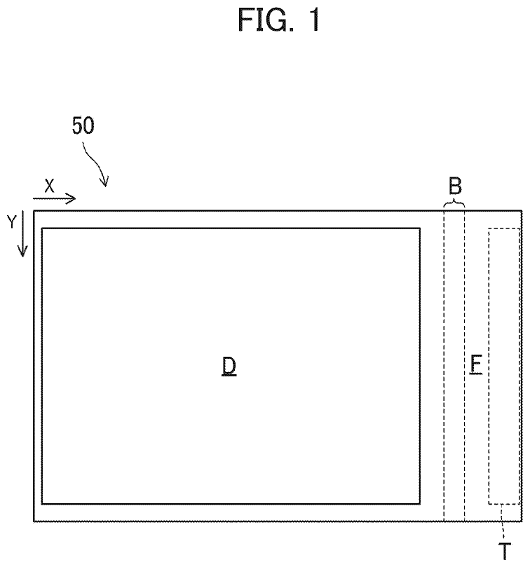

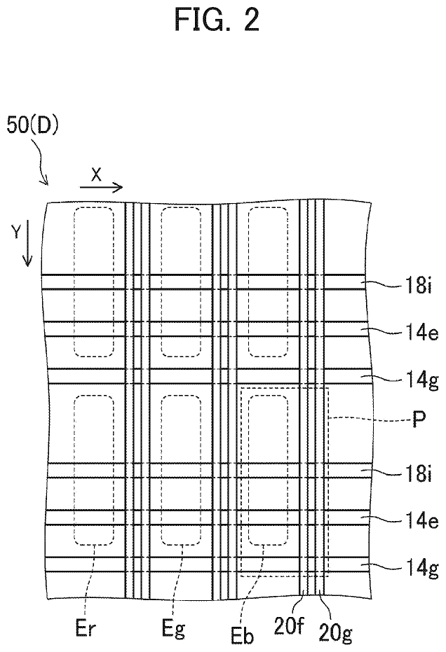

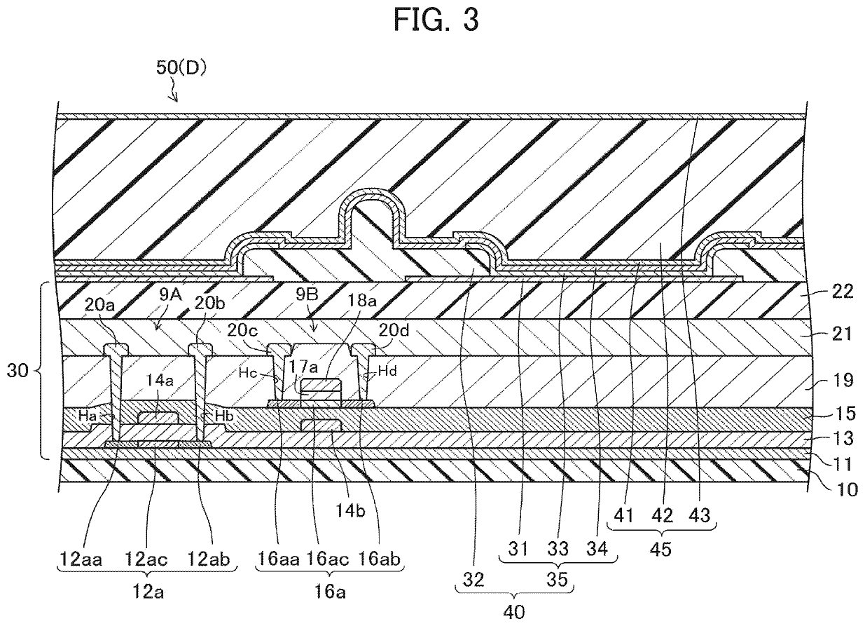

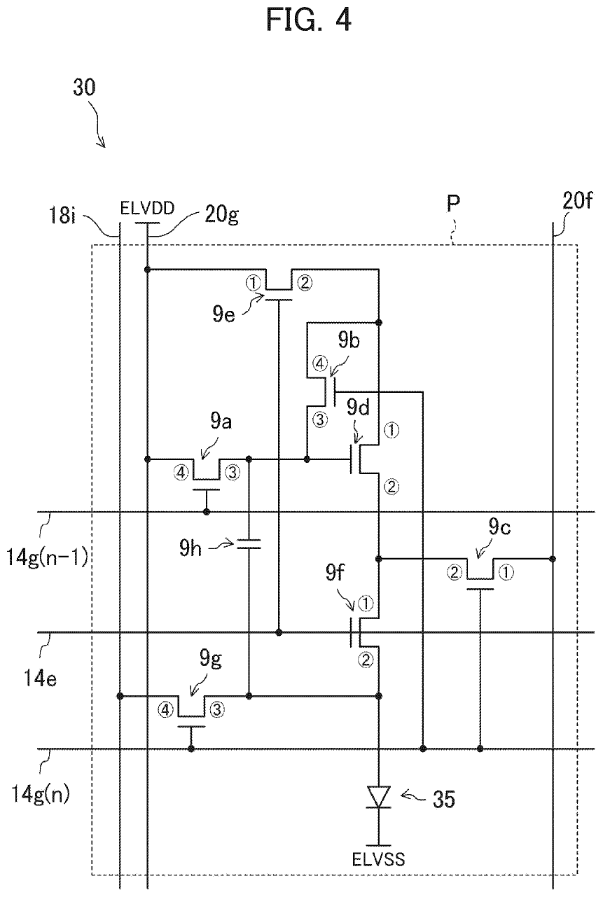

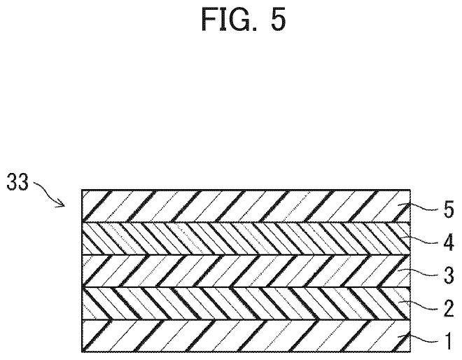

FIGS. 1 to 5 illustrate a first embodiment of a display device according to the present invention. Note that, in the embodiments below, an organic EL display device including an organic-EL-element layer is exemplified as a display device including a light-emitting-element layer. Here, FIG. 1 is a plan view of a schematic configuration of an organic EL display device 50 according to this embodiment. FIG. 2 and FIG. 3 are respectively a plan view and a cross-sectional view of a display region D of the organic EL display device 50. FIG. 4 is an equivalent circuit diagram of the TFT layer 30 included in the organic EL display device 50. FIG. 5 is a cross-sectional view of an organic EL layer 33 included in the organic EL display device 50.

As illustrated in FIG. 1, the organic EL display device 50 includes, for example: the display region D shaped into a rectangle and displaying an image; and a picture-frame region F provided around the display region D. Note that this embodiment exemplifies the display region D shaped into a rectangle. Examples of the rectangle include such substantial rectangles as a rectangle having arc-like sides, a rectangle having rounded corners, and a rectangle having partially notched sides.

The display region D illustrated in FIG. 2 includes a plurality of subpixels P arranged in a matrix. Moreover, in the display region D, as illustrated in FIG. 2, for example, subpixels P having red light-emitting regions Er for presenting red, subpixels P having green light-emitting regions Eg for presenting green, and subpixels P having blue light-emitting regions Eb for presenting blue are provided side by side. Note that, in the display region D, for example, neighboring three subpixels P each having one of a red light-emitting region Er, a green light-emitting region Eg, and a blue light-emitting region Eb constitute one pixel.

The picture-frame region F in FIG. 1 has an end portion in the positive X-direction. The end portion is provided with a terminal unit T extending in one direction (in a Y-direction in FIG. 1). Moreover, as illustrated in FIG. 1, the picture-frame region F includes, for example, a folding portion B between the display region D and the terminal unit T. The folding portion B, extending in one direction (in the Y-direction in the drawing), is foldable around a folding axis in the Y-direction in the drawing at an angle of 180° (foldable in a U-shape).

As illustrated in FIG. 3, the organic EL display device 50 includes: a resin substrate 10 provided as a base substrate; a TFT layer 30 provided on the resin substrate 10; an organic-EL-element layer 40 having a top-emission configuration and provided on the TFT layer 30 to serve as a light-emitting-element layer; and a sealing film 45 provided on the organic-EL-element layer 40.

The resin substrate 10 is made of, for example, an organic resin material such as polyimide resin.

The TFT layer 30 illustrated in FIG. 3 includes: a base coat film 11 provided on the resin substrate 10; four first TFTs 9A, three second TFTs 9B, and one capacitor 9h all of which are provided on the base coat film 11 for each of the subpixels P (see FIG. 4); and a protective insulating film 21 and a planarization film 22 sequentially provided above each of the first TFTs 9A, the second TFTs 9B, and the capacitor 9h. Here, the TFT layer 30 includes, as illustrated in FIG. 2, a plurality of gate lines 14g extending in parallel with one another in an X-direction in the drawing. Furthermore, the TFT layer 30 includes, as illustrated in FIG. 2, a plurality of light-emission control lines 14e extending in parallel with one another in the X-direction in the drawing. Moreover, the TFT layer 30 includes, as illustrated in FIG. 2, a plurality of second initialization power supply lines 18i extending in parallel with one another in the X-direction in the drawing. Note that, as illustrated in FIG. 2, the light-emission control lines 14e are provided side by side with the gate lines 14g and the second initialization power supply lines 18i. Furthermore, the TFT layer 30 includes, as illustrated in FIG. 2, a plurality of source lines 20f extending in parallel with one another in the Y-direction in the drawing. Moreover, the TFT layer 30 includes, as illustrated in FIG. 2, a plurality of power supply lines 20g extending in parallel with one another in the Y-direction in the drawing. Note that, as illustrated in FIG. 2, the power supply lines 20g and the source lines 20f are provided side by side.

The TFT layer 30 illustrated in FIG. 3 includes: the base coat film 11; a first semiconductor film; a first gate insulating film 13; a first metal film; a first interlayer insulating film 15; a second semiconductor film; a second gate insulating film 17a; a second metal film; a second interlayer insulating film 19; a third metal film; the protective insulating film 21; and the planarization film 22, all of which are sequentially stacked on top of another above the resin substrate 10. Here, the gate lines 14g and the light-emission control lines 14e are formed of the first metal film. Furthermore, the second initialization power supply lines 18i are formed of the second metal film. Moreover, the source lines 20f and the power supply lines 20g are formed of the third metal film.

Each of the base coat film 11, the first gate insulating film 13, the first interlayer insulating film 15, the second gate insulating film 17a, the second interlayer insulating film 19, and the protective insulating film 21 is a monolayer inorganic insulating film made of such a substance as, for example, silicon nitride, silicon oxide, or silicon oxynitride. Alternatively, each film is a multilayer inorganic insulating film made of these substances. Here, the first interlayer insulating film 15 and the second gate insulating film 17a have respective portions toward the second semiconductor layer 16a, and at least the portions are made of, for example, silicon oxide films. Note that the first gate insulating film 13, the first interlayer insulating film 15, the second gate insulating film 17a, the second interlayer insulating film 19, and the protective insulating film 21 are respectively provided to serve as a first inorganic insulating film, a second inorganic insulating film, a third inorganic insulating film, a fourth inorganic insulating film, and a fifth inorganic insulating film.

As illustrated in FIG. 3, each of the first TFTs 9A includes: a first semiconductor layer 12a provided on the base coat film 11; a first gate electrode 14a provided above the first semiconductor layer 12a through the first gate insulating film 13; and a first terminal electrode 20a and a second terminal electrode 20b provided on the second interlayer insulating film 19 and spaced apart from each other.

The first semiconductor layer 12a is formed of the first semiconductor film made of, for example, polysilicon such as low-temperature polysilicon (LTPS). As illustrated in FIG. 3, the first semiconductor layer 12a includes: a first conductor region 12aa and a second conductor region 12ab defined to be spaced apart from each other; and a first channel region 12ac defined between the first conductor region 12aa and the second conductor region 12ab.

The first gate electrode 14a is formed of the first metal film. As illustrated in FIG. 3, the first gate electrode 14a is provided to overlap with the first channel region 12ac of the first semiconductor layer 12a. The first gate electrode 14a controls conduction between the first conductor region 12aa and the second conductor region 12ab of the first semiconductor layer 12a.

The first terminal electrode 20a and the second terminal electrode 20b are formed of the third metal film. As illustrated in FIG. 3, the first terminal electrode 20a and the second terminal electrode 20b are respectively and electrically connected to the first conductor region 12aa and the second conductor region 12ab of the first semiconductor layer 12a through a first contact hole Ha and a second contact hole Hb formed in a multilayer film including the first gate insulating film 13, the first interlayer insulating film 15, and the second interlayer insulating film 19.

As illustrated in FIG. 3, each of the second TFTs 9B includes: the second semiconductor layer 16a provided on the first interlayer insulating film 15; a second gate electrode 18a provided above the second semiconductor layer 16a through the second gate insulating film 17a; a third gate electrode 14b provided to the second semiconductor layer 16a toward the resin substrate 10 through the first interlayer insulating film 15; and a third terminal electrode 20c and a fourth terminal electrode 20d provided on the second interlayer insulating film 19 and spaced apart from each other.

The second semiconductor layer 16a is formed of the second semiconductor film made of, for example, an In—Ga—Zn—O-based oxide semiconductor. As illustrated in FIG. 3, the second semiconductor layer 16a includes: a third conductor region 16aa and a fourth conductor region 16ab defined to be spaced apart from each other; and a second channel region 16ac defined between the third conductor region 16aa and the fourth conductor region 16ab. Here, the In—Ga—Zn—O-based oxide semiconductor is a ternary oxide of indium (In), gallium (Ga), and zinc (Zn), and a ratio (a composition ratio) of In to Ga to Zn is not limited to a particular ratio. Furthermore, the In—Ga—Zn—O-based oxide semiconductor may be amorphous or crystalline. Note that the crystalline In—Ga—Zn—O-based oxide semiconductor is preferably a crystalline In—Ga—Zn—O-based semiconductor in which the c-axis is oriented substantially perpendicular to the layer plane. Moreover, instead of the In—Ga—Zn—O-based semiconductor, the second semiconductor layer 16a may contain another oxide semiconductor. Examples of the other oxide semiconductor may include an In—Sn—Zn—O-based semiconductor (e.g., In₂O₃—SnO₂—ZnO; InSnZnO). Here, the In—Sn—Zn—O-based semiconductor is a ternary oxide of indium (In), tin (Sn), and zinc (Zn). In addition, other oxide semiconductors may include: an In—Al—Zn—O-based semiconductor; an In—Al—Sn—Zn—O-based semiconductor; a Zn—O-based semiconductor; an In—Zn—O-based semiconductor; a Zn—Ti—O-based semiconductor; a Cd—Ge—O-based semiconductor; a Cd—Pb—O-based semiconductor; cadmium oxide (CdO); a Mg—Zn—O-based semiconductor; an In—Ga—Sn—O-based semiconductor; an In—Ga—O-based semiconductor; a Zr—In—Zn—O-based semiconductor; a Hf—In—Zn—O-based semiconductor; an Al—Ga—Zn—O-based semiconductor; a Ga—Zn—O-based semiconductor; an In—Ga—Zn—Sn—O-based semiconductor; InGaO₃(ZnO)₅; zinc magnesium oxide (MgₓZn₁₋ₓO), and zinc cadmium oxide (CdₓZn₁₋ₓO). Note that the Zn—O-based semiconductor may be ZnO doped with one or more kinds of impurity elements among a group 1 element, a group 13 element, a group 14 element, a group 15 element, and a group 17 element. The Zn—O-based semiconductor may be in an amorphous state, in a polycrystalline state, or in a microcrystalline state in which an amorphous state and a polycrystalline state are mixed together. Alternatively. the Zn—O-based semiconductor does not have to be doped with any impurity element.

The second gate electrode 18a is formed of the second metal film. As illustrated in FIG. 3, the second gate electrode 18a is provided to overlap with the second channel region 16ac of the second semiconductor layer 16a. The second gate electrode 18a controls conduction between the third conductor region 16aa and the fourth conductor region 16ab of the second semiconductor layer 16a. Here, as illustrated in FIG. 3, the second gate insulating film 17a below the second gate electrode 18a is shaped into an island shape, and provided to overlap with the second gate electrode 18a.

The third gate electrode 14b is formed of the first metal film. As illustrated in FIG. 3, the third gate electrode 14b is provided to overlap with the second channel region 16ac of the second semiconductor layer 16a. The third gate electrode 14b is electrically connected to the second gate electrode 18a in order to control conduction between the third conductor region 16aa and the fourth conductor region 16ab of the second semiconductor layer 16a. Furthermore, the third gate electrode 14b overlaps with the second channel region 16ac of the second semiconductor layer 16a, in order to reduce such risks as light intruding into the second channel region 16ac and impurity ions in the resin substrate 10 reaching the second channel region 16ac. Note that the third gate electrode 14b can be omitted because, as will be described later, the planarization film 22 keeps short-wavelength light from intruding into the second channel region 16ac.

The third terminal electrode 20c and the fourth terminal electrode 20d are formed of the third metal film. As illustrated in FIG. 3, the third terminal electrode 20c and the fourth terminal electrode 20d are respectively and electrically connected to the third conductor region 16aa and the fourth conductor region 16ab of the second semiconductor layer 16a through a third contact hole Hc and a fourth contact hole Hd formed in the second interlayer insulating film 19.

In this embodiment, a write TFT 9c, a drive TFT 9d, a power supply TFT 9e, and a light-emission control TFT 9f to be described later are exemplified as the four first TFTs 9A each having the first semiconductor layer 12a formed of polysilicon, and an initialization TFT 9a, a compensation TFT 9b, and an anode discharge TFT 9g to be described later are exemplified as the three second TFTs 9B each having the second semiconductor layer 16a formed of oxide semiconductor (see FIG. 4). Note that, in the equivalent circuit diagram in FIG. 4, the first terminal electrode 20a and the second terminal electrode 20b of each of the TFTs 9c, 9d, 9e, and 9f are denoted by circled numerals 1 and 2, and the third terminal electrode 20c and the fourth terminal electrode 20d of each of the TFTs 9a, 9b, and 9g are denoted by circled numerals 3 and 4. Furthermore, the equivalent circuit diagram in FIG. 4 illustrates a pixel circuit of a subpixel P at the n-th row and the m-th column. The equivalent circuit diagram also partially includes a pixel circuit of a subpixel P at the (n−1)-th row and the m-th column. In addition, in the equivalent circuit diagram in FIG. 4, the power supply line 20g to supply a high power-supply voltage ELVDD also serves as a first initialization power supply line; however, the power supply line 20g and the first initialization power supply line may be provided separately. Moreover, the second initialization power supply line 18i receives, but not limited to, the same voltage as a low power-supply voltage ELVSS. The second initialization power supply line 18i may receive a voltage that differs from the low power-supply voltage ELVSS, and that turns OFF an organic EL element 35 to be described later.

As illustrated in FIG. 4, in each subpixel P, the initialization TFT 9a has: a gate electrode electrically connected to a gate line 14g(n−1) in a preceding stage (n−1 stage); the third terminal electrode electrically connected to a lower conductive layer of the capacitor 9h and to a gate electrode of the drive TFT 9d; and the fourth terminal electrode electrically connected to the power supply line 20g.

As illustrated in FIG. 4, in each subpixel P, the compensation TFT 9b has: a gate electrode electrically connected to a gate line 14g(n) in a corresponding stage (n-th stage); the third terminal electrode electrically connected to the gate electrode of the drive TFT 9d; and the fourth terminal electrode electrically connected to the first terminal electrode of the drive TFT 9d.

As illustrated in FIG. 4, in each subpixel P, the write TFT 9c has: a gate electrode electrically connected to the gate line 14g(n) in the corresponding stage (n-th stage); the first terminal electrode electrically connected to a corresponding source line 20f; and the second terminal electrode electrically connected to the second terminal electrode of the drive TFT 9d.

As illustrated in FIG. 4, in each subpixel P, the drive TFT 9d has: the gate electrode electrically connected to the third terminal electrode of each of the initialization TFT 9a and the compensation TFT 9b; the first terminal electrode electrically connected to the fourth terminal electrode of the compensation TFT 9b and to the second terminal electrode of the power supply TFT 9e; and the second terminal electrode electrically connected to the second terminal electrode of the write TFT 9c and to the first terminal electrode of the light-emission control TFT 9f. Here, the drive TFT 9d controls a drive current of the organic EL element 35.

As illustrated in FIG. 4, in each subpixel P, the power supply TFT 9e has: a gate electrode electrically connected to a light-emission control line 14e in the corresponding stage (n-th stage); the first terminal electrode electrically connected to the power supply line 20g; and the second terminal electrode electrically connected to the first terminal electrode of the drive TFT 9d.

As illustrated in FIG. 4, in each subpixel P, the light-emission control TFT 9f has: a gate electrode electrically connected to the light-emission control line 14e in the corresponding stage (n-th stage); the first terminal electrode electrically connected to the second terminal electrode of the drive TFT 9d; and the second terminal electrode electrically connected to a first electrode 31 of the organic EL element 35. The first electrode 31 and the organic EL element 35 will be described later.

As illustrated in FIG. 4, in each subpixel P, the anode discharge TFT 9g has: a gate electrode electrically connected to the gate line 14g(n) in the corresponding stage (n-th stage); the third terminal electrode electrically connected to the first electrode 31 of the organic EL element 35; and the fourth terminal electrode electrically connected to a second initialization power supply line 18i.

The capacitor 9h includes, for example: a lower conductive layer (not shown) formed of the first metal film; the first interlayer insulating film 15 and a second gate insulating film (not shown) provided to cover the lower conductive layer; and an upper conductive layer (not shown) formed of the second metal film and provided on the second gate insulating film to overlap with the lower conductive layer. Moreover, as illustrated in FIG. 4, in each subpixel P, the capacitor 9h has: the lower conductive layer electrically connected to the gate electrode of the drive TFT 9d and to the third terminal electrode of each of the initialization TFT 9a and the compensation TFT 9b; and the upper conductive layer electrically connected to the third terminal electrode of the anode discharge TFT 9g, to the second terminal electrode of the light-emission control TFT 9f, and to the first electrode 31 of the organic EL element 35.

The planarization film 22, which has a flat surface in the display region D, is formed of, for example, an organic resin material such as a red acrylic resin. For example, the planarization film 22 includes a red color filter with which a transmittance of light having a wavelength of approximately 420 nm to 570 nm is set to be substantially 0%. The planarization film 22 is provided so that a transmittance of light having a wavelength of 450 nm or shorter is set lower than a transmittance of light having a wavelength longer than 450 nm. Hence, the planarization film 22 reduces transmission of light having a wavelength of 450 nm or shorter. Here, this embodiment exemplifies a case where the planarization film 22 is formed of an organic resin material. The planarization film 22 may be, for example, a red color filter formed of an inorganic multilayer film including titanium oxide films and silicon oxide films alternately stacked on top of another. Alternatively, the planarization film 22 may contain, for example, a black organic resin material capable of blocking light. Note that if the planarization film 22 having a flat surface is formed of an inorganic multilayer film, the surface may be planarized by such a technique as, for example, chemical mechanical polishing (CMP). Furthermore, the planarization film 22 is provided so that, at least in a portion included in the planarization film 22 and overlapping with the second TFT 9B, a transmittance of light having a wavelength of 450 nm or shorter is set lower than a transmittance of light having a wavelength longer than 450 nm.

The organic-EL-element layer 40 illustrated in FIG. 3 includes: a plurality of the first electrodes 31; an edge cover 32 provided in common; a plurality of the organic EL layers 33; and a second electrode 34 provided in common, all of which are sequentially stacked on top of another in association with the plurality of subpixels P. Here, in each of the subpixels P, a first electrode 31, an organic EL layer 33, and the second electrode 34 constitute an organic EL element 35 as illustrated in FIG. 3. In the organic-EL-element layer 40, a plurality of the organic EL elements 35 is arranged in a matrix in association with the plurality of subpixels P.

The first electrode 31 is electrically connected through a contact hole formed in a multilayer film including the protective insulating film 21 and the planarization film 22 to the second terminal electrode of the light-emission control TFT 9f for each subpixel P. Furthermore, the first electrode 31 has a function of injecting holes into the organic EL layer 33. Moreover, the first electrode 31 is preferably formed of a material having a large work function to improve efficiency in injecting the holes into the organic EL layer 33. Here, the first electrode 31 is formed of, for example, a multilayer film including: a transparent conductive film made of such a substance as indium tin oxide (ITO); a metal film made of such a metal as silver (Ag); and a transparent conductive film made of such a substance as ITO, all of which are sequentially stacked on top of another. The first electrode 31 is reflective to light.

The first edge cover 32 is provided in a grid pattern over the entire display region D. As illustrated in FIG. 3, the first edge cover 32 is provided to cover a peripheral end portion of the first electrode 31. Here, the edge cover 32 is made of, for example, an organic resin material such as polyimide resin or acrylic resin, or a polysiloxane-based spin-on-glass (SOG) material.

As illustrated in FIG. 5, the organic EL layer 33 includes: a hole injection layer 1; a hole transport layer 2; a light-emitting layer 3, an electron transport layer 4, and an electron injection layer 5, all of which are provided in the stated order above the first electrode 31.

The hole injection layer 1 is also referred to as an anode buffer layer. The hole injection layer 1 has a function of approximating energy levels between the first electrode 31 and the organic EL layer 33 to improve efficiency in injecting the holes from the first electrode 31 into the organic EL layer 33. Here, examples of a material forming the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has a function of improving efficiency in transporting the holes from the first electrode 31 to the organic EL layer 33. Here, examples of a material forming the hole transport layer 2 include a porphyrin derivative, an aromatic tertiary amine compound, a styrylamine derivative, polyvinyl carbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, zinc selenide, and zinc selenide.

The light-emitting layer 3 is a region where the holes and the electrons are respectively injected from the first electrode 31 and the second electrode 34, and recombine together, when a voltage is applied with the first electrode 31 and the second electrode 34. Here, the light-emitting layer 3 is formed of a material having high light-emission efficiency. Examples of the material forming the light-emitting layer 3 include a metal oxinoid compound [8-hydroxyquinoline metal complex], a naphthalene derivative, an anthracene derivative, a diphenylethylene derivative, a vinylacetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rhodamine derivative, an aquizine derivative, phenoxazone, a quinacridone derivative, rubrene, poly-p-phenylenevinylene, and polysilane.

The electron transport layer 4 has a function of efficiently moving the electrons to the light-emitting layer 3. Here, examples of a material forming the electron transport layer 4 include, as organic compounds, an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has a function of approximating energy levels between the second electrode 34 and the organic EL layer 33 to improve efficiency in injecting the electrons from the second electrode 34 into the organic EL layer 33. Such a function can decrease a drive voltage of the organic EL element 35. Note that the electron injection layer 5 is also referred to as a cathode buffer layer. Here, examples of a material forming the electron injection layer 5 include: inorganic alkali compounds such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the second electrode 34 is provided in common to all the subpixels P to cover each organic EL layer 33 and the edge cover 32. Moreover, the second electrode 34 has a function of injecting the electrons into the organic EL layer 33. Furthermore, the second electrode 34 is preferably formed of a material having a small work function to improve efficiency in injecting the electrons into the organic EL layer 33. Here, the second electrode 34 is, for example, a transparent conductive film formed of such a substance as ITO. The second electrode 34 is transparent to light.

As illustrated in FIG. 3, the sealing film 45 is provided to cover the second electrode 34, and includes: a first inorganic sealing film 41; an organic sealing film 42; and a second inorganic sealing film 43, all of which are sequentially stacked on top of another above the second electrode 34. The sealing film 45 has a function of protecting the organic EL layer 33 in the organic EL element 35 from moisture and oxygen.

Each of the first inorganic sealing film 41 and the second inorganic sealing film 43 is formed of such an inorganic insulating film as, for example, a silicon nitride film, a silicon oxide film, or a silicon oxynitride film.

The organic sealing film 42 is formed of such an organic resin material as, for example, acrylic resin, epoxy resin, silicone resin, polyurea resin, parylene resin, polyimide resin, or polyamide resin.

As to the organic EL display device 50 having the above configuration, in each subpixel P, when the light-emission control line 14e is first selected to be in an inactive state, the organic EL element 35 is in a non-light-emission state. In the non-light-emission state, the gate line 14g(n−1) in the preceding stage is selected. Through the gate line 14g(n−1), a gate signal is input into the initialization TFT 9a such that the initialization TFT 9a turns ON. Hence, the high power-supply voltage ELVDD of the power supply line 20g is applied to the capacitor 9h, and the drive TFT 9d turns ON. Thus, charges of the capacitor 9h are discharged, and a voltage to be applied to the gate electrode of the drive TFT 9d is initialized. Next, when the gate line 14g(n) of the corresponding stage is selected to be in the active state, the compensation TFT 9b and the write TFT 9c turn ON, and a predetermined voltage corresponding to a source signal to be transmitted through the corresponding source line 20f is written into the capacitor 9h through the drive TFT 9d connected to a diode. Simultaneously, the anode discharge TFT 9g turns ON, and an initialization signal is applied through the second initialization power supply line 18i to the first electrode 31 of the organic EL element 35. Hence, the charges stored in the first electrode 31 are reset. After that, the light-emission control line 14e is selected, and the power supply TFT 9e and the light-emission control TFT 9f turn ON. Hence, a drive current corresponding to the voltage applied to the gate electrode of the drive TFT 9d is supplied from the power supply line 20g to the organic EL element 35. Thus, in each subpixel P, the organic EL element 35 having a top-emission configuration emits light at the luminance corresponding to the drive current. This is how the organic EL display device 50 displays an image.

Described next will be a method for producing the organic EL display device 50 of this embodiment. Note that the method for producing the organic EL display device 50 includes: a TFT-layer forming step; an organic-EL-element-layer forming step; and a sealing-film forming step.

### TFT-Layer Forming Step

First, for example, a silicon nitride film (approximately 50 nm in thickness) and a silicon oxide film (approximately 250 nm in thickness) are sequentially deposited by, for example, plasma chemical vapor deposition (CVD) on the resin substrate 10 formed on a glass substrate. Hence, the base coat film 11 is formed.

Then, on a substrate surface provided with the base coat film 11, an amorphous silicon film (approximately 50 nm in thickness) is deposited by, for example, the plasma CVD. The amorphous silicon film is crystallized by such a technique as laser annealing to form the first semiconductor film formed of polysilicon. After that, the first semiconductor film is patterned to form such a layer as the first semiconductor layer 12a.

After that, on the substrate surface provided with the first semiconductor layer 12a, a silicon oxide film (approximately 100 nm in thickness) is deposited by, for example, the plasma CVD to form the first gate insulating film 13.

Furthermore, on the substrate surface provided with the first gate insulating film 13, a first metal film such as a molybdenum film (approximately 200 nm in thickness) is formed by, for example, sputtering. After that, the first metal film is patterned to form, for example, the first gate electrode 14a, the third gate electrode 14b, the gate line 14g, and the light-emission control line 14e.

Then, using the first gate electrode 14a as a mask, the first semiconductor layer 12a is doped with impurity ions so that a portion of the first semiconductor layer 12a becomes conductive to form the first conductor region 12aa, the second conductor region 12ab, and the first channel region 12ac in the first semiconductor layer 12a.

After that, on the substrate surface of the conductive portion in the first semiconductor layer 12a, a silicon nitride film (approximately 150 nm in thickness) and a silicon oxide film (approximately 100 nm in thickness) are sequentially deposited by, for example, the plasma CVD. Hence, the first interlayer insulating film 15 is formed.

Furthermore, on the substrate surface provided with the first interlayer insulating film 15, the second semiconductor film of an oxide semiconductor formed of such a substance as an InGaZnO₄ film (approximately 30 nm in thickness) is deposited by, for example, sputtering. After that, the second semiconductor film is patterned to form the second semiconductor layer 16a.

Subsequently, on the substrate surface provided with such a layer as the second semiconductor layer 16a, a silicon oxide film (approximately 100 nm in thickness) is deposited by, for example, the plasma CVD. After that, the second metal film such as a molybdenum film (approximately 200 nm in thickness) is deposited by, for example, sputtering. The second metal film is patterned to form such constituent features as the second gate electrode 18a and the second initialization power supply line 18i.

After that, the silicon oxide film exposed from, for example, the second gate electrode 18a is etched to form such a film as the second gate insulating film 17a.

Moreover, on the substrate surface provided with, for example, the second gate insulating film 17a, a silicon oxide film (approximately 300 nm in thickness) and a silicon nitride film (approximately 150 nm in thickness) are sequentially deposited by, for example, the plasma CVD. Hence, the second interlayer insulating film 19 is formed. Note that, by heat treatment after the formation of the second interlayer insulating film 19, a portion of the second semiconductor layer 16a becomes conductive to form the third conductor region 16aa, the fourth conductor region 16ab, and the second channel region 16ac in the second semiconductor layer 16a.

Subsequently, on the substrate surface provided with the second interlayer insulating film 19, the first gate insulating film 13, the first interlayer insulating film 15, and the second interlayer insulating film 19 are patterned as appropriate. Hence, contact holes are formed.

After that, on the substrate surface having the contact holes, a titanium film (approximately 50 nm in thickness), an aluminum film (approximately 400 nm in thickness), and a titanium film (approximately 100 nm in thickness) are sequentially deposited by, for example, sputtering to form the third metal film. After that, the third metal film is patterned to form such constituent features as the first terminal electrode 20a, the second terminal electrode 20b, the third terminal electrode 20c, the fourth terminal electrode 20d, the source line 20f, and the power supply line 20g.

Furthermore, on the substrate surface provided with such a constituent feature as the first terminal electrode 20a, a silicon oxide film (approximately 250 nm in thickness) is deposited by, for example, the plasma CVD to form the protective insulating film 21.

Subsequently, the substrate surface provided with the protective insulating film 21 is coated with an acrylic-based photosensitive resin film colored red (approximately 2 μm in thickness) by, for example, spin coating or slit coating. After that, the coating film is pre-baked, exposed to light, developed, and post-baked to form the planarization film 22 having a contact hole.

Finally, the protective insulating film 21 exposed from the contact hole of the planarization film 22 is removed, so that the contact hole reaches the second drain electrode 20b of the second pixel TFT 9b.

As described above, the TFT layer 30 is successfully formed.

### Organic-EL-Element-Layer Forming Step

On the planarization film 22 of the TFT layer 30 formed at the TFT-layer forming step, the first electrode 31, the edge cover 32, the organic EL layer 33 (including the hole injection layer 1, the hole transport layer 2, the light-emitting layer 3, the electron transport layer 4, and the electron injection layer 5), and the second electrode 34 are formed, using a known technique. Hence, the organic-EL-element layer 40 is formed.

### Sealing-Film Forming Step

First, on the substrate surface provided with the organic-EL-element layer 40 formed at the organic-EL-element-layer forming step, an inorganic insulating film such as, for example, a silicon nitride film, a silicon oxide film, or a silicon oxynitride film is deposited by the plasma CVD, using a mask. Hence, the first inorganic sealing film 41 is formed.

Then, on the substrate surface provided with the first inorganic sealing film 41, an organic resin material such as acrylic resin is deposited by, for example, inkjet printing. Hence, the organic sealing film 42 is formed.

After that, on the substrate surface provided with the organic sealing film 42, an inorganic insulating film such as, for example, a silicon nitride film, a silicon oxide film, or a silicon oxynitride film is deposited by the plasma CVD, using a mask, to form the second inorganic sealing film 43. Hence, the sealing film 45 is formed.

Finally, a protective sheet (not shown) is attached to the substrate surface provided with the sealing film 45. After that, a laser beam is emitted from toward the glass substrate of the resin substrate 10, and the glass substrate is removed from a lower surface of the resin substrate 10. To the lower surface of the resin substrate 10 from which the glass substrate is removed, a protective sheet (not shown) is attached.

As can be seen, the organic EL display device 50 of this embodiment is successfully produced.

As described above, the organic EL display device 50 of this embodiment includes: the first TFT 9A having the first semiconductor layer 12a formed of polysilicon; and the second TFT 9B having the second semiconductor layer 16a formed of oxide semiconductor. The first TFT 9A and the second TFT 9B are provided for each of the subpixels P. Hence, the organic EL display device 50 has a hybrid structure. Furthermore, the organic EL display device 50 has the planarization film 22 provided to the first TFT 9A and the second TFT 9B toward the light-emitting-element layer 40, so that, thanks to the planarization film 22, a transmittance of light having a wavelength of 450 nm or shorter is set lower than a transmittance of light having a wavelength longer than 450 nm. Here, the second TFT 9B having the second semiconductor layer 16a formed of oxide semiconductor is likely to deteriorate because of a threshold value shift caused by a blue light or a green light having a relatively short wavelength. However, the second TFT 9B is less likely to deteriorate because the threshold value does not shift thanks to a red light having a relatively long wavelength. Hence, even if stray light is generated from the light emitted from the organic EL element 35 toward the sealing film 45, the planarization film 22 blocks short wavelength components of the stray light; that is, a blue light and a green light. As a result, only a long wavelength component; that is, a red light, reaches the second TFT 9B. Such a feature reduces deterioration of the second TFT 9B by light, thereby successfully reducing light-induced deterioration of a TFT formed of oxide semiconductor and included in the hybrid organic EL display device 50.

### Other Embodiments

In the above embodiment, the exemplified organic EL layer has a multilayer structure including five layers such as a hole injection layer, a hole transport layer, a light-emitting layer, an electron transport layer, and an electron injection layer. Alternatively, the organic EL layer may have a multilayer structure including three layers such as, for example, a hole-injection-and-hole-transport layer, a light-emitting layer, and an electron-transport-and-electron-injection layer.

In addition, in the above embodiment, the organic EL display device is exemplified as a display device. The present invention can be applied to a display device including a plurality of light-emitting elements driven by currents. For example, the present invention can be applied to a display device including quantum-dot light-emitting diodes (QLEDs); that is, light-emitting elements including layers containing quantum dots.

### INDUSTRIAL APPLICABILITY

As described above, the present invention is useful for a flexible display device.

### REFERENCE SIGNS LIST

D Display Region
P Subpixel
9A First TFT (First Thin-Film Transistor)
9B Second TFT (Second Thin-Film Transistor)
9a Initialization TFT (Second Thin-Film Transistor)
9b Compensation TFT (Second Thin-Film Transistor)
9c Write TFT (First Thin-Film Transistor)
9d Drive TFT (First Thin-Film Transistor)
9e Power Supply TFT (First Thin-Film Transistor)
9f Light-Emission Control TFT (First Thin-Film Transistor)
9g Anode Discharge TFT (Second Thin-Film Transistor)
10 Resin Substrate (Base Substrate)
12a First Semiconductor Layer
12aa First Conductor Region
12ab Second Conductor Region
12ac First Channel Region
13 First Gate Insulating Film (First Inorganic Insulating Film)
14a First Gate Electrode
15 First Interlayer Insulating Film (Second Inorganic Insulating Film)
16a Second Semiconductor Layer
16aa Third Conductor Region
16ab Fourth Conductor Region
12ac Second Channel Region
17a Second Gate Insulating Film (Third Inorganic Insulating Film)
18a Second Gate Electrode
19 Second Interlayer Insulating Film (Fourth Inorganic Insulating Film)
20a First Terminal Electrode
20b Second Terminal Electrode
20c Third Terminal Electrode
20d Fourth Terminal Electrode
21 Protective Insulating Film (Fifth Inorganic Insulating Film)
30 TFT Layer (Thin-Film Transistor Layer)
31 First Electrode
33 Organic EL Layer (Organic Electroluminescent Layer, Light-Emitting Functional Layer)
34 Second Electrode
40 Organic-EL-Element Layer (Light-Emitting Element Layer)
45 Sealing Film
50 Organic EL Display Device

1. A display device, comprising:
a base substrate;
a thin-film transistor layer provided on the base substrate; and
a light-emitting-element layer having a top-emission configuration and provided on the thin-film transistor layer,
wherein the thin-film transistor layer includes: a first thin-film transistor having a first semiconductor layer formed of polysilicon; a second thin-film transistor having a second semiconductor layer formed of oxide semiconductor; and a planarization film provided to the first thin-film transistor and the second thin-film transistor toward the light-emitting-element layer, the first thin-film transistor and the second thin-film transistor being provided for each of a plurality of subpixels included in a display region, and
the planarization film is provided so that a transmittance of light having a wavelength of 450 nm or shorter is set lower than a transmittance of light having a wavelength longer than 450 nm.

2. The display device according to claim 1,
wherein the planarization film includes a red color filter.

3. The display device according to claim 2,
wherein the planarization film contains a red organic resin material.

4. The display device according to claim 1,
wherein the planarization film contains a black organic resin material.

5. The display device according to claim 1,
wherein the thin-film transistor layer includes: a first semiconductor film to serve as the first semiconductor layer; a first inorganic insulating film; a first metal film; a second inorganic insulating film; a second semiconductor film to serve as the second semiconductor layer; a third inorganic insulating film; a second metal film; a fourth inorganic insulating film; a third metal film; a fifth inorganic insulating film; and the planarization film, all of which are sequentially stacked on top of another from toward the base substrate to toward the light-emitting-element layer.

6. The display device according to claim 5,
wherein the first thin-film transistor includes: the first semiconductor layer; a first gate electrode; and a first terminal electrode and a second terminal electrode, the first semiconductor layer including: a first conductor region and a second conductor region defined to be spaced apart from each other; and a first channel region defined between the first conductor region and the second conductor region, the first gate electrode being formed of the first metal film and provided above the first semiconductor layer through the first inorganic insulating film, and the first terminal electrode and the second terminal electrode being formed of the third metal film, spaced apart from each other, and respectively and electrically connected to the first conductor region and the second conductor region.

7. The display device according to claim 5,
wherein the second thin-film transistor includes: the second semiconductor layer; a second gate electrode; and a third terminal electrode and a fourth terminal electrode, the second semiconductor layer including: a third conductor region and a fourth conductor region defined to be spaced apart from each other; and a second channel region defined between the third conductor region and the fourth conductor region, the second gate electrode being formed of the second metal film and provided above the second semiconductor layer through the third inorganic insulating film, and the third terminal electrode and the fourth terminal electrode being formed of the third metal film, spaced apart from each other, and respectively and electrically connected to the third conductor region and the fourth conductor region.

8. The display device according to claim 1,
wherein the light-emitting-element layer includes: a plurality of first electrodes; a plurality of light-emitting functional layers; and a second electrode provided in common, all of which are sequentially stacked on top of another from toward the thin-film transistor layer and away from the thin-film transistor layer and are provided in association with the plurality of subpixels included in the display region,
each of the first electrodes is reflective to light, and
the second electrode is transparent to light.

9. The display device according to claim 8, further comprising
a sealing film provided on the light-emitting-element layer.

10. The display device according to claim 8,
wherein each of the light-emitting functional layers is an organic electroluminescent layer.
